(19) United States
(12) Patent Application Publication
(10) Pub. No.: US 2008/0195903 A1
(43) Pub. Date: Aug. 14, 2008

(54) NON-VOLATILE MEMORY DEVICE WITH BUILT-IN TEST CONTROL UNIT AND METHODS OF TESTING AND REPAIRING A CELL ARRAY

(75) Inventor: Volker Zipprich-Rasch, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA FLASH GMBH & CO. KG, Dresden (DE)

(21) Appl. No.: 11/674,853

(22) Filed: Feb. 14, 2007

(51) Int. Cl. G11C 29/44

(52) U.S. Cl. 714/721

(57) ABSTRACT

A memory device including a cell array is disclosed. One embodiment includes a plurality of memory cells, wherein each memory cell is capable of showing at least two distinguishable states, a programmable read voltage source adapted to supply an alterable read voltage and a test control unit. The test control unit includes a voltage control unit that is capable of controlling the read voltage source, a counter unit that is capable of counting the memory cells exhibiting a predetermined state and an analysis unit that is capable of rating a currently determined number of memory cells exhibiting a predetermined state.

### BACKGROUND

Embodiments of the present invention relate to methods of testing and repairing a cell array having a plurality of memory cells and to memory devices.

Conventional non-volatile memory devices broadly fall into two different categories, floating gate and trapping layer. Trapping layer memory cells, such as SONOS-memories or NROM-memories, have an n-channel FET with the gate dielectric replaced by a trapping layer and two barrier layers sandwiching the trapping layer. The trapping layer is the storage element of the memory cell. The barrier layers inhibit direct tunneling of charge carriers from and to the non-conductive trapping layer. Floating gate memory cells include usually an n-channel FET with a floating gate sandwiched between a dielectric tunnel layer separating the floating gate from the transistors channel region and a dielectric barrier layer between the floating gate and the control gate that is connected to the address circuitry. The floating gate is the storage element of the memory cell. The tunnel dielectric and the dielectric barrier layer insulate the conductive floating gate. A memory cell may be programmed by injecting charge carriers into the trapping layer or the floating gate from either the control gate or the channel region. The memory cell may be erased by removing or compensating the previously injected charge. The embodiments of the current invention are not limited to these two different categories of non-volatile memories and may cover other types of solutions.

Memory cells may be based on a binary or a multi-level programming/sensing scheme, for example a 4-bit per cell programming/sensing scheme. According to the binary programming/sensing scheme, the n-channel FET of a trapping layer or floating gate memory switches from a non-conductive state to a conductive state, when a read voltage applied to the control gate exceeds a threshold voltage. The n-channel FET returns to the non-conductive state, when the read voltage falls below the threshold voltage. A negative charge that is stored in the storage element functions as a negative bias of the control gate and shifts the threshold voltage towards higher voltage values.

The state of the memory cell is detected by applying a suitable read voltage to the control gate and checking whether the FET is conductive or not. In this case, the read voltage is selected such that, on one hand, the read voltage is high enough to ensure that all erased memory cells are conductive and that, on the other hand, the read voltage is low enough to ensure that none of the programmed memory cells is non-conductive.

According to a 4-bit per cell programming/sensing scheme, three different amounts of charge are injected into the same area or equivalent amounts of charge are stored in different locations of the storage element. Three different threshold voltage levels are used to define four different ranges or states. Each of the four different ranges or states represents a unique arrangement of a pair of bits (e.g., 00, 01, 10 or 11).

The threshold voltage of each memory cell depends on, to some extent, geometric and physical properties of the respective memory cell. For example, channel length, channel doping profile, and/or barrier layer thickness vary from memory cell to memory cell, due to fluctuations or imperfections of process steps required in course of the fabrication of the memory device. As a result, the threshold voltage varies from memory cell to memory cell. For each cell array with a plurality of memory cells, a characterizing threshold voltage distribution results.

Conventionally, a memory cell that exhibits a threshold voltage outside a predetermined range either for the erased state or for the programmed state is classified as being defective and is replaced by a redundant repair cell if applicable. However, identifying memory cells that might affect the performance of the memory device during lifetime remains a general design and test requirement.

### SUMMARY

One embodiment refers to a method of testing a cell array. In a distribution section near a distribution edge, a distribution gradient of a threshold voltage distribution of the cell array is determined by varying a read voltage applied to the cell array. The distribution gradient in the distribution section is compared to a limit gradient. If the distribution gradient exceeds the limit gradient, an inner distribution edge is determined by a read voltage, at which the distribution gradient exceeds the limit gradient. Memory cells that exhibit a threshold voltage in a range between the distribution edge and the inner distribution edge may be classified as being defective.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a diagram illustrating a threshold voltage distribution of a cell array with a plurality of binary memory cells both for a programmed state of the memory cells and for an erased state of the memory cells.

FIG. 2 illustrates a diagram illustrating an inconspicuous threshold voltage distribution and a further threshold voltage distribution showing a distribution tail for a cell array with programmed memory cells.

FIG. 3 illustrates a flow chart of a method of testing a cell array having binary programmable/erasable memory cells by assessment of an upper threshold voltage distribution section according to an embodiment of the invention.

FIG. 4 illustrates a flow chart of a further method of testing and repairing a cell array having binary programmable/erasable memory cells by assessment of a lower threshold voltage distribution section according to a further embodiment of the invention.

FIG. 5 illustrates a flow chart of a method of testing a cell array having binary programmable/erasable memory cells by predicting the distribution edge according to another embodiment of the invention.

FIG. 6 illustrates a schematic block diagram of a memory device with a test control unit according to a further embodiment of the invention.

FIG. 7 illustrates a schematic block diagram of a memory device with a test control unit and a repair unit according to a further embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

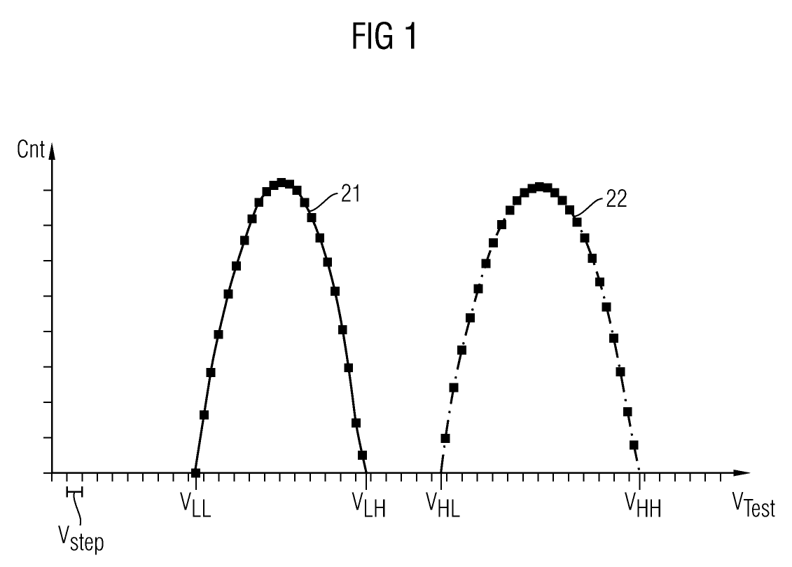

FIG. 1 is a diagram depicting an exemplary threshold voltage distribution of a cell array having a plurality of binary memory cells. The diagram plots a memory cell count against a test voltage for the programmed state and the erased state respectively. The abscissa indicates a test voltage Vtest and is scaled to a step voltage Vstep. The ordinate indicates the respective memory cell count. A first threshold voltage distribution curve 21 shows the number of erased memory cells switching to the conductive state at the respective test voltage. A second threshold voltage distribution 22 indicates the number of programmed memory cells that switch to the conductive state at the respective test voltage. Each curve 21, 22 may represent substantially a gaussian distribution, wherein the distribution for the programmed state tends to be wider than the distribution for the erased state. The first curve 21 referring to erased memory cells has a lower distribution edge VLL and an upper distribution edge VLH. The second plot 22 referring to programmed memory cells has a lower distribution edge VHL and an upper distribution edge VHH.

By applying a test voltage lower than VLL to a cell array with erased and programmed memory cells, none of the memory cells, whether programmed or erased, is conductive and no information can be obtained from the cell array. Applying a test voltage higher than VLL but lower than VLH would cause only a portion of the erased cells to becoming conductive. By applying a test voltage higher than VHH, all programmed memory cells become conductive and no information can be obtained from the cell array. Applying a test voltage lower than VHH but higher than VHL would cause only a portion of the programmed cells to becoming conductive. For obtaining the correct information from each memory cell, the read voltage must be in the range of a “sense window” between VLH and VHL.

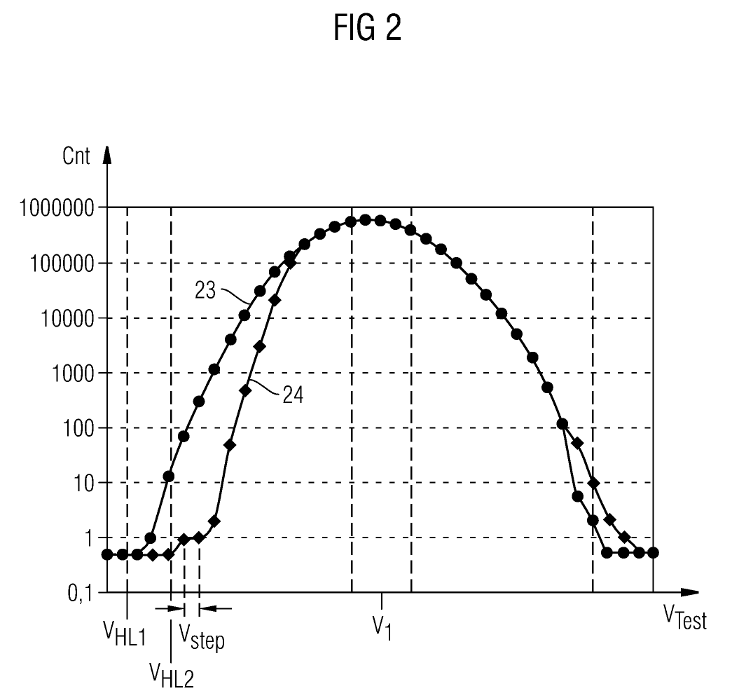

FIG. 2 shows a diagram that plots a cell count Cnt against a test voltage Vread. A first threshold voltage distribution 23 is assigned to a typical cell array without conspicuous memory cells. The threshold voltage distribution 23 may refer to either a programmed or an erased state of the cell array. If, for example, the threshold voltage distribution 23 refers to a binary floating gate or nitride-based trapping layer cell array with all memory cells being programmed, a first lower threshold voltage VHL1 that is obtained from the lower distribution edge of the first threshold voltage distribution 23 represents an upper limit for the read voltage that may be applied to the cell array during operation. A read voltage lower than VHL1 ensures that all programmed memory cells are non-conductive and are detectable as being programmed. Applying a read voltage higher than VHL1 would cause at least some of the programmed memory cells to becoming conductive such that they would wrongly be detected as being erased. The threshold voltage of a memory cell is a function of a plurality of geometric and physical parameters that in each case depend on manufacturing parameters typically fluctuating according to a normal distribution. As a consequence, if the cell array includes a sufficient number of memory cells, the first threshold voltage distribution 23 follows also essentially a Gaussian distribution.

The diagram of FIG. 2 shows further a second threshold voltage distribution 24 assigned to a second cell array. A second lower threshold limit VHL2 assigned to the lower distribution edge of the second threshold voltage distribution 24 is higher than VHL1. According to a first approach, the second cell array may operate properly for a read voltage below VHL2. The second threshold voltage distribution 24, however, deviates conspicuously from the expected Gaussian distribution. The deviation becomes obvious particularly with regard of a section confining to the lower distribution edge of the second threshold voltage distribution. Though in the main the second threshold voltage distribution 24 do follow a Gaussian distribution, a comparable small number of memory cells leave the Gaussian-like distribution. These memory cells appear to be less sensitive to a program cycle. This fact may be a hint of an abnormality in the manufacturing process, e.g., a particle contamination, wherein the process abnormality may weak the affected memory cells in some respect and thus shorten life expectancy of the affected memory cells. Test methods according to the following exemplary embodiments of the invention may identify conspicuous memory cells and may therefore contribute to improving the reliability of memory devices.

Thus here explained in detail for an upper distribution edge of a erased binary non-volatile cell array with memory cells of trapping layer memories, the same idea applies accordingly to a lower distribution edge, to programmed cell arrays, to floating gate memories and to multi-bit or multi-level memory cell architectures, by way of example.

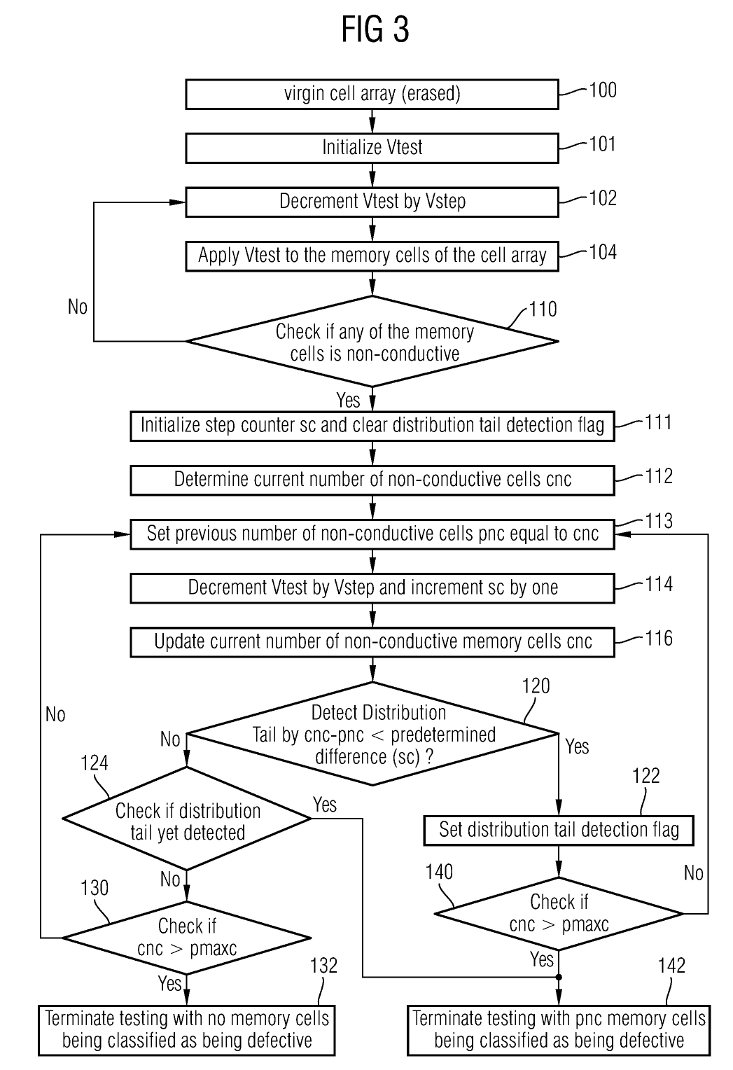

A test method for memory devices according to an exemplary embodiment of the invention is illustrated in the flowchart of FIG. 3. FIG. 3 refers to a method assessing the threshold voltage distribution of a virgin or an erased cell array, but it is appreciated that the invention is not limited to the threshold voltage distribution of erased cell arrays and the invention may be applied to other cell arrays, such as but not limited to programmed cell arrays.

A cell array with binary trapping layer memory cells may be initialized by erasing all memory cells or by programming all memory cells (100). The cell array may include a plurality of memory cells that are assigned to the same sense amplifier or erase section in order to eliminate adulterations of the threshold voltage distribution resulting from support circuitry. In an exemplary embodiment, initialization of the memory cells is omitted and a virgin cell array is tested, wherein manufacturing induced cell abnormalities may become more evident.

A test voltage Vtest may be initialized by being set equal to a start voltage Vstart incremented by a step voltage Vstep (101). According to an exemplary embodiment, the start voltage is selected such that by applying a test voltage higher than the start voltage all memory cells of the cell array remain conductive and are detected as being erased. Various methods for predicting a suitable start voltage are possible. For example, the start voltage may be obtained from a previous test procedure in course of which a sense window applicable for the cell array is determined. Alternatively, a technology dependent average read voltage may serve as start voltage. The start voltage may be readjusted by further process steps (not shown) if required, for example, if the gradient of the distribution gives a hint for an improper choice of the start voltage.

The step voltage is usually predetermined by the resources of the memory device or an external test apparatus. Usually a voltage source for supplying the read voltage is programmable in steps of for example 50 mV in order to facilitate an adjustment of the read voltage within a respective sense window and in order to track the read voltage to a shift of the sense window during the life cycle of the memory device.

The test voltage Vtest may be decremented then by the step voltage (102) such that in the following a test voltage Vtest equal to the start voltage Vstart is applied to the memory cells of the cell array (104). Other embodiments may provide a first decrementing (102) after a first comparison (110).

The cell array is read out by applying the test voltage to the control gates of each memory cell (104). The storage elements, for example the trapping layer or the floating gate of a virgin or of an erased memory cell should be discharged and the respective control gate should not be biased. Each memory cell is checked whether it is in the non-conductive state (110). If none of the memory cells has yet switched into the non-conductive state, the test voltage is again decremented by the step voltage (102). The cell array is rescanned for non-conductive memory cells (104). Decrementing the test voltage (102), applying the test voltage (104), and scanning for conductive memory cells (110) are repeated until at least one non-conductive memory cell is detected. If at least one non-conductive memory is detected, therewith implicitly an outer upper distribution edge of the threshold voltage distribution is detected, which is equal to the current test voltage. A step counter sc and/or a distribution tail detection flag may be initialized or cleared (111) and a current number count of non-conductive cells cnc may be determined (112). Determination of cnc may be omitted, for example, if the current number count cnc is yet determined in course of the scanning for non-conductive cells. A temporary, previously detected number count of non-conductive cells pnc may be set equal to the current number count (113).

The test voltage is further decremented by the step voltage and the step counter may be incremented by one (114). The current number count cnc may be updated by being set equal to the number of all memory cells having yet switched into the non-conductive state at the current test voltage (116). Alternatively, only the number of memory cells having switched to the non-conductive state in course of the respectively last incrementing step may be determined by either masking out the memory cells having switched into the non-conductive state during a previous incrementing step or by obtaining a new current number count cnc through counting the number of non-conductive memory cells at the current test voltage and subtracting the previously obtained number count pnc.

The information obtained so far is analyzed (120), wherein in either case the gradient of the threshold voltage distribution in a distribution section near the outer upper distribution edge is assessed. For this purpose, the difference between the current number count cnc and the previously obtained number count pnc may be evaluated. If the difference is too small and falls below a predetermined limit, then a distribution tail is detected as illustrated in the second threshold voltage distribution 24 of FIG. 2, wherein the distribution tail indicates that the concerned memory cells are conspicuous.

If the difference is sufficiently large, the current number count cnc may be compared to a predetermined maximum count pmaxc (130). If the current number count cnc does not exceed the predetermined maximum count pmaxc, the previously number count pnc may be overwritten with the current number count cnc (113) and decrementing Vtest, incrementing sc (114), updating the current number count (116), and assessing the distribution gradient (120) may be repeated until a distribution tail is detected or until the predetermined maximum count pmaxc is surpassed by the current number count cnc. In the latter case, the test sequence is terminated without any memory cells being classified as being unreliable or defective (132). The predetermined gradient may be set in dependence on the current value of the step counter in order to get a more flexible approach.

If the difference between the current number count cnc and the previously obtained number count pnc is not sufficiently large and falls below the predetermined limit, then a distribution tail is detected. The current number count cnc may be compared to the predetermined maximum count pmaxc (140). If the current number count cnc exceeds the predetermined maximum count pmaxc, the test sequence may be terminated by classifying memory cells assigned to the previously obtained number count pnc as being defective (142). As long as the current number count cnc does not exceed the predetermined maximum count pmaxc, overwriting pnc with cnc (113), decrementing Vtest, incrementing sc (114), updating cnc (116), and assessing the distribution gradient (120) may be repeated. In this case, only a portion of a longer distribution tail may be determined, wherein as many conspicuous memory cells as possible are identified.

For avoiding the loss of a short distribution tail, a distribution tail detection flag may be set, when a distribution tail is detected at the first time (122). The distribution tail detection flag may be checked when no distribution tail is detected within the current loop, i.e. when the distribution gradient is qualified as not being conspicuous for the current step count. Once a distribution tail is detected, the test sequence may be terminated with the previously obtained non-conductive memory cells pnc as being classified as being assigned to the distribution tail and therefore as being defective (142). In this case, the complete distribution tail may be detected.

Alternatively or additionally, in a further step (not shown) the step counter may be assessed. If, for a predetermined limit of the step counter, the current number count does not exceed a further predetermined limit count that may be equal to the predetermined maximum count, the memory cells that has yet been detected as being non-conductive may be classified as being defective.

The method may be implemented both in an external test apparatus or in a built-in circuitry within the respective memory device. The non-conductive memory cells may be counted by a counter unit that is implemented as integral part of a test control unit being provided within the memory device. The test control unit may be a centralized one controlling the test sequence for all cell arrays within the memory device or a distributed one, wherein each cell array of the memory device is assigned to one test control unit and wherein each test control unit is assigned to one cell array. As a distribution tail concerns a comparable small number of cells, the required circuitry is comparable simple and does not require much resources with regard to space and test time.

A counter unit that is assigned to one sense amplifier may be a simple three or four digit counter.

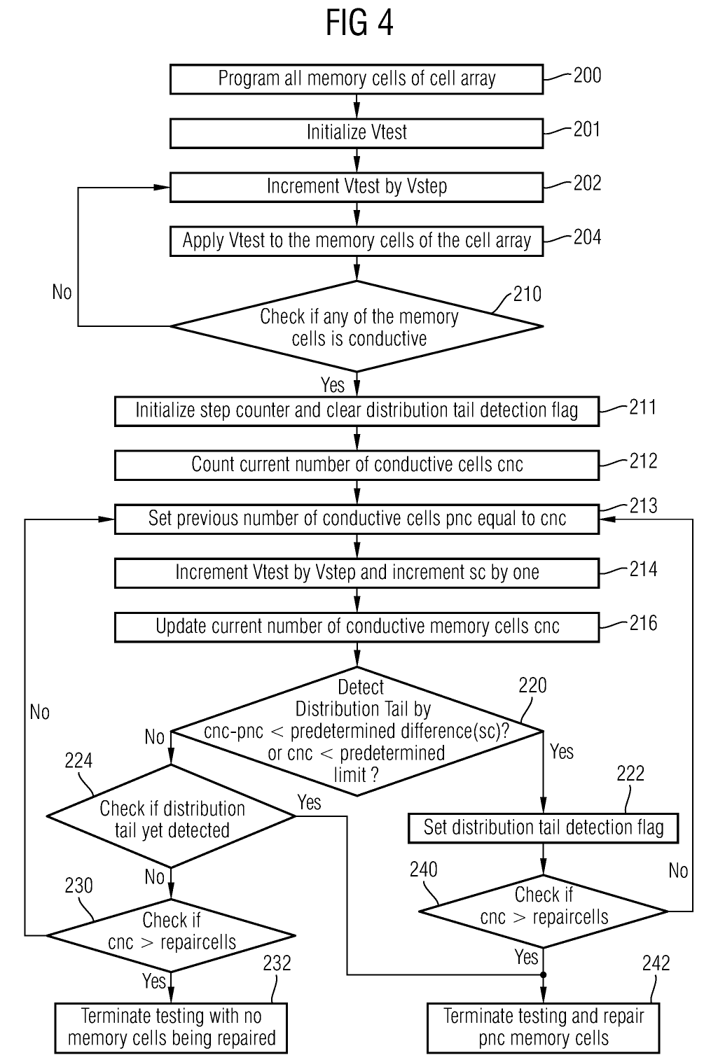

While the method according to FIG. 3 refers to the assessment of a distribution section adjoining the upper distribution edge, FIG. 4 refers to a method for assessing a distribution section adjoining a lower distribution edge. The method of FIG. 4 corresponds widely to that of FIG. 3 and the following description focuses on the differences.

The cell array may be completely programmed (200) and a test voltage Vtest may be initialized by being set equal to a lower start voltage Vstart decremented by the step voltage Vstep (201), wherein the lower start voltage is selected such that all memory cells of the programmed cell array remain non-conductive, when a test voltage lower than the lower start voltage is applied. The methods for predicting a suitable lower start voltage may correspond to that for predicting a suitable upper start voltage as discussed above.

The test voltage Vtest may then be incremented by the step voltage (202) such that in the following a test voltage Vtest equal to the start voltage Vstart is applied to the memory cells of the cell array (204). Other embodiments may provide a first incrementing (202) after a first comparison (210).

The cell array is read out by applying the test voltage to the control gates of each memory cell (204). The state of each memory cell is sensed (210). If none of the memory cells has yet switched into the conductive state, the test voltage is again incremented by the step voltage (202) and the cell array is rescanned for conductive memory cells (204). Incrementing the test voltage (202), applying the test voltage (204), and scanning for conductive memory cells (210) are repeated until at least one conductive memory cell is detected. The lowest test voltage, at which at least one conductive memory cell is detected, defines an outer lower distribution edge of the threshold voltage distribution. Operations (211) to (224) correspond to the respectively corresponding operations (111) to (124), wherein the current number count cnc and the previously detected number count pnc refer in this case to a number of conductive cells respectively and wherein the test voltage is further incremented instead of being decremented as long as the current number count cnc of conductive cells does not exceed a maximum fail count pmaxc.

Thus the gradient of the threshold voltage distribution in a distribution section near the outer lower distribution edge is assessed by evaluating the difference between the current number count cnc and the previously obtained number count pnc. Memory cells with a threshold voltage in the range of the detected distribution tail may be qualified as being defective or unreliable and the respective pass/fail information may be transmitted via a signaling interface of the device to a test apparatus. Alternatively or additionally, the information about conspicuous memory cells is stored in a bad block mapping register of the memory device.

Referring to operations (230), (240), the maximum fail count pmaxc may correspond to a number of available repair cells assigned to the tested cell array. A pass/fail information identifying conspicuous memory cells is alternatively or additionally transmitted to a repair unit. The repair unit controls the allocation of repair cells to address lines and data lines such that each detected conspicuous memory cell may be replaced by a repair cell (242). The repair unit may be provided completely within the memory device.

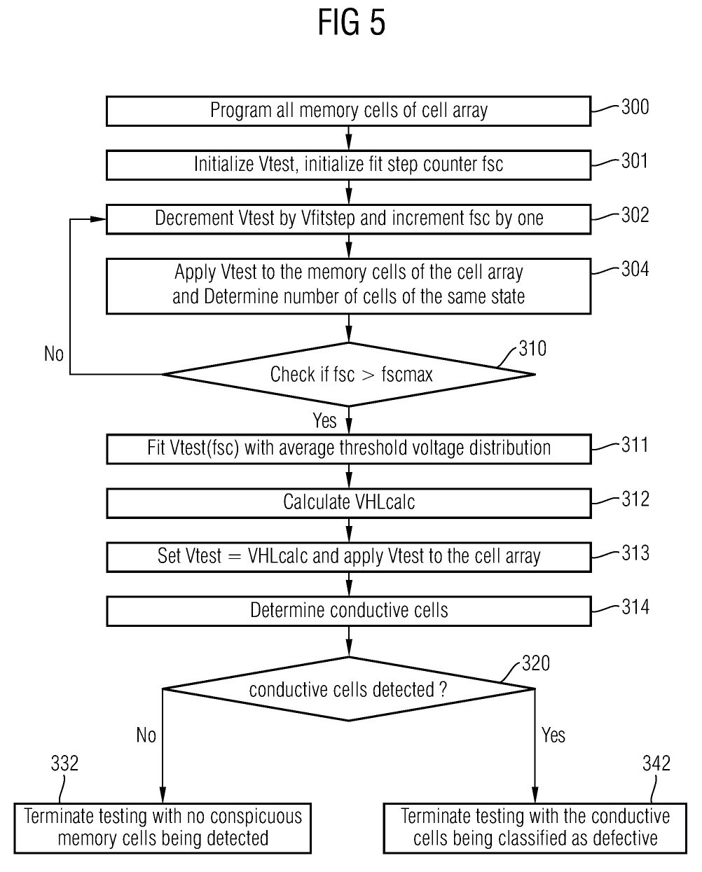

The flowchart of FIG. 5 illustrates a further method of testing a cell array, wherein the method may be realized through a sequential control of an off-chip test apparatus. The cell array is initialized, for example by programming all memory cells (300). A test voltage Vtest is initialized by being set equal to an expected medium value of the voltage distribution incremented by a fit step voltage Vfitstep. A fit step counter fsc is reset (301). The test voltage is decremented by the fit step voltage Vfitstep and the fit step counter is incremented (302). The test voltage is applied to the memory cells of the cell array and the number of memory cells having the same state, conductive or non-conductive, is determined for the respective test voltage (304). Decrementing the test voltage (302), applying the test voltage, and determining the number of memory cells having the same state are repeated (304) until the fit step counter exceeds a limit fscmax.

The start voltage may be obtained by determining and averaging threshold voltage distributions of a plurality of cell arrays that are based on the same manufacturing process. The fit step voltage and the number of repetitions result from the requirement of obtaining suitable basic values that enable a good interpolation of the respective distribution edge and from the requirement of a short test time. In an exemplary embodiment referring to a typical distribution width of 1.5V, the counts for three to five test voltages may be determined, wherein the fit step test voltage may range from 100 mV to 300 mV. Alternatively, the step voltage may differ from step to step. Via a fitting algorithm, the basic values of the actual threshold voltage distribution are compared to an average voltage distribution that characterizes the respective cell array (311). An inner lower distribution edge VHLcalc is predicted for the actual threshold voltage distribution (312). The test voltage Vtest is set equal to the predicted lower distribution edge and applied to the memory cells (313). The cell array is scanned for conductive cells (313). Memory cells that are in the conductive state at the predicted lower distribution edge are harder to program than it could be expected. Thus, if conductive cells are detected, they are supposed to be conspicuous or unreliable in some way. The conductive cells are therefore classified as being defective and may be replaced to improve the reliability of the cell array and the memory device.

The basic values of the actual threshold voltage distribution may be obtained for the whole distribution between the lower distribution edge and the higher distribution edge, wherein both a lower VHLcalc and a higher VHHcalc distribution edge may be predicted. With respect to the reliablity of the memory cells, the assessment may be limited to the respective distribution edge confining to a “sense window”, i.e., for a cell array with binary memory cells VLHcalc and VHLcalc, wherein the basic values may be obtained only from the respective half of the threshold voltage distribution.

Since not a complete threshold voltage distribution, but only a comparable small number of basic values is determined and transferred to an off-chip test apparatus for calculating the predicted distribution edges, the method is comparable fast. According to another embodiment, the test method is executed via circuitry that is realized completely within the memory device. Then, according to another exemplary embodiment, alternative algorithms that may require less circuitry may be implemented in order to detect a distribution tail.

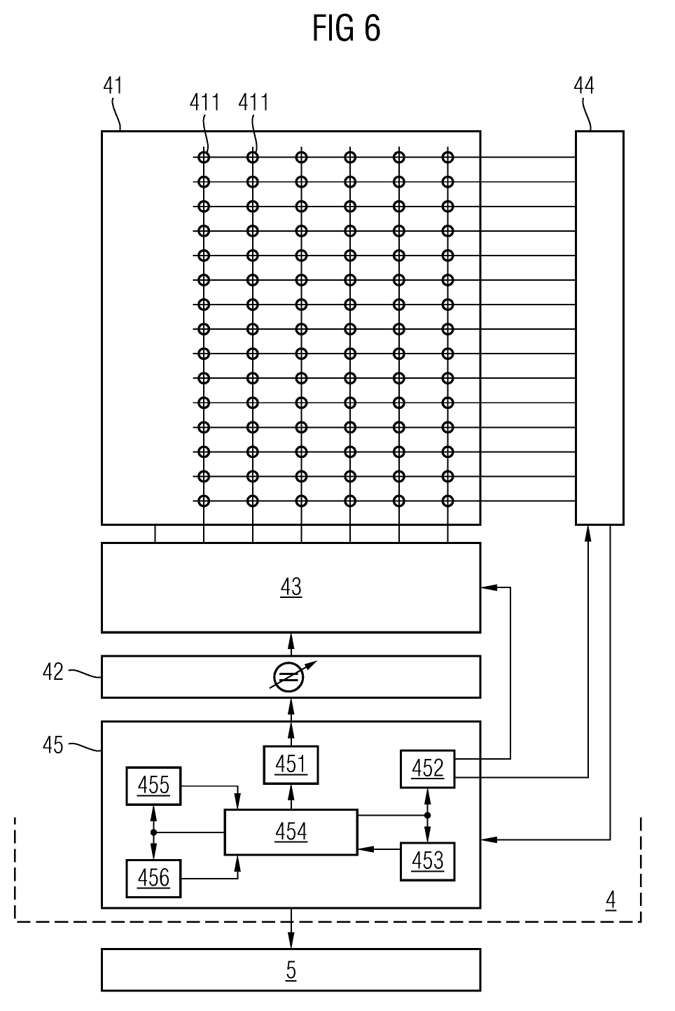

FIG. 6 is a schematical illustration of a memory device 4 configured to identifying conspicuous memory cells. The memory device 4 includes a cell array 41 that includes a plurality of memory cells 411. Each memory cell 411 is capable of switching a digital, e.g., binary, output signal in response to a read voltage, wherein the sensitivity to the read voltage depends on the current data content of the respective memory cell 411 and on statistical deviations due to manufacturing fluctuations and process imperfections. Each memory cell 411 is configured to showing at least two distinguishable states, wherein by applying a read voltage below a threshold voltage a first state of the respective memory cell 411 is detected and wherein by applying a read voltage beyond the threshold voltage a second state of the respective memory 411 cell is detected. In case of a FET-based memory cell 411, the first state may be the non-conductive state and the second state may be the conductive state.

The memory device 4 may include further a programmable read voltage source 42 for supplying the read voltage, wherein the read voltage is alterable in steps defined by a step voltage. A test control unit 45 of the memory device 4 may be provided in a centralized manner, wherein each cell array 41 is assigned to the same test control unit 45, or in a distributed manner, wherein one test control unit 45 is provided per cell array 41. The test control unit 45 may be connected to the read voltage source 42 and includes a voltage control unit 451 being capable of controlling the read voltage source 42 in dependence on the results of a threshold voltage distribution assessment. The test control unit 45 further may include an array control unit 452 configured to controlling read operations concerning the memory cells 411 through a sense unit 44 and an address unit 43, at least one counter unit 453 for counting the memory cells 411 having a predefined state, e.g., all conductive or all non-conductive memory cells 411, and an analysis unit 454 configured to evaluating the memory cells 411 on basis of the respectively obtained number of memory cells 411 exhibiting a predetermined state.

The counter unit 453 may be assigned to a complete cell array 41 or to one of the sense amplifiers of the cell array 41. Then, as only a section of the threshold voltage distribution is evaluated that represents a comparable small number of memory cells 411, a small three or four-digit counter may be sufficient.

In an exemplary embodiment, the test control unit 45 may include a data storage unit 455 capable of temporarily storing at least the respective previously obtained cell count before the cell count is overwritten by a currently determined current cell count. The analysis unit 454 may be further suitable to compare the currently obtained cell count with the previously obtained cell count. The comparison may concern the cell counts directly or values that are deduced from the cell count in a way to qualify deviations with regard to an average distribution gradient in a suitable way.

According to another exemplary embodiment, the test control unit 45 includes alternatively or additionally to the storage unit 455 a step counter 456 that is capable of counting a step number of increments/decrements of the test voltage, wherein the analysis unit 454 may be configured to rating the cell array 41 by comparing the currently obtained number with a predetermined value assigned to the respective step number. The assessment of the distribution tail may then be based on more than one assessment criterion or on a very simple criterion. Alternatively or additionally, test cycle time may be minimized, if one of the criterions indicates a normal or non-conspicuous distribution. The test control unit 454 may further be configured to classifying memory cells assigned to the previously obtained number of memory cells as being defective.

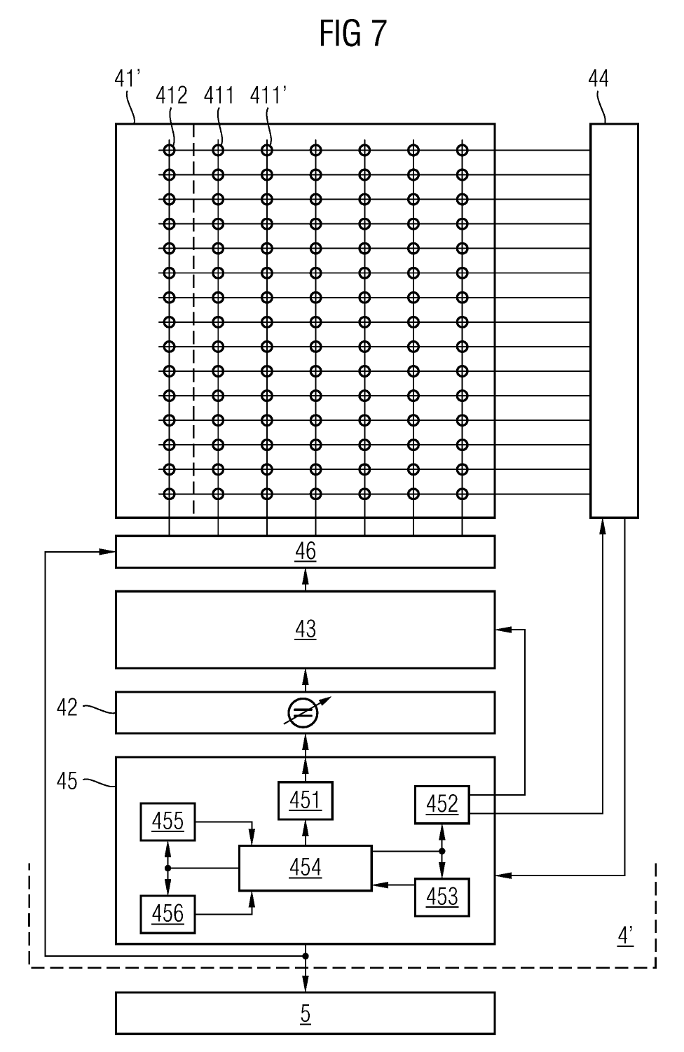

FIG. 7 illustrates schematically a further memory device 4′ configured to identifying and substituting conspicuous memory cells. With regard to the memory device 4 of FIG. 6, the memory device 4′ includes further a repair unit 46 and the cell array 41″ includes repair cells 412. The test control unit 45 is configured to transmitting information identifying conspicuous memory cells 411 to the repair unit 46. The repair unit 46 is capable of masking out conspicuous memory cells 411 either with regard to the address line side or the data line side, wherein conspicuous cells are substituted by repair cells 412.

While specific embodiments of the invention has been described in detail, it will be apparent to one skilled in the art that various changes and modifications can be made therein without departing from the spirit and the scope thereof. Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of testing a cell array, comprising:
determining a distribution gradient of a threshold voltage distribution of the cell array in a distribution section near a distribution edge by varying a read voltage applied to the cell array;
comparing the distribution gradient in the distribution section to a limit gradient;
assigning, in case of the distribution gradient exceeding the limit gradient, an inner distribution edge to a read voltage, at which the distribution gradient exceeds the limit gradient; and
classifying memory cells that exhibit a threshold voltage in a range between the distribution edge and the inner distribution edge as being defective.

2. The method of claim 1, wherein a first state of a memory cell of the cell array is detectable by applying a read voltage below a threshold voltage and wherein a second state of the memory cell is detectable by applying a read voltage beyond the threshold voltage.

3. The method of claim 2, wherein the distribution gradient and the inner distribution edge are determined by:
determining an average voltage threshold distribution;
applying successively predetermined read voltages to the cell array and determining in each case the number of memory cells exhibiting the same state to determine an actual threshold voltage distribution of the cell array;
fitting the actual threshold voltage distribution with the average voltage threshold distribution; and
setting the inner distribution edge equal to a predicted distribution edge of the fitted actual threshold voltage distribution.

4. The method of claim 1, wherein the distribution gradient is determined by determining the distribution edge of the threshold voltage distribution; and
successively applying predetermined read voltages to the cell array and determining in each case the number of memory cells exhibiting the same state.

5. The method of claim 4, wherein the distribution edge is a lower edge of the threshold voltage distribution and wherein a distribution gradient exceeding the limit gradient falls below the limit gradient.

6. The method of claim 4, wherein the distribution edge is an upper edge of the threshold voltage distribution.

7. The method of claim 5, wherein determining the distribution edge of the threshold voltage distribution comprises:
setting the read voltage to a start voltage at which each memory cell is detected as having the same start state;
repeatedly incrementing/decrementing the read voltage by a step voltage and applying the read voltage to the memory cells until at least one memory cell is detected as having another state than the start state; and
setting the distribution edge equal to the read voltage at which the at least one memory cell is detected as having another state than the start state.

8. The method of claim 7, wherein determining the distribution gradient of the threshold voltage distribution in the distribution section comprises:
repeatedly incrementing/decrementing the read voltage from the lower/upper distribution edge by a predetermined step voltage and applying the respective read voltage to the memory cells; and
counting in each case the memory cells being detected as having another state than the start state.

9. The method of claim 4, wherein determining the limit gradient comprises:
determining threshold voltage distribution gradients of a plurality of equivalent functional cell arrays; and
averaging the threshold voltage distribution gradients.

10. A method of repairing a cell array, comprising:
determining a distribution edge of a threshold voltage distribution of the cell array;
determining a distribution gradient of the threshold voltage distribution in a distribution section near the distribution edge;
comparing the distribution gradient in the distribution section with a limit gradient and assigning, in case of the distribution gradient exceeding the limit gradient, an inner distribution edge to a read voltage at which the distribution gradient exceeds the limit gradient;
classifying memory cells that exhibit a threshold voltage in a range between the distribution edge and the inner distribution edge as being defective; and
repairing the memory cells classified as being defective by replacing them with repair cells.

11. The method of claim 10, wherein the cell array comprises a plurality of user data memory cells and a plurality of repair cells, the memory cells and repair cells being capable of showing at least two distinguishable states, wherein a first state of the respective memory cell is detectable by applying a read voltage below a threshold voltage and wherein a second state of the respective memory cell is detectable by applying a read voltage beyond the threshold voltage.

12. The method of claim 10, wherein determining the distribution edge of the threshold voltage distribution comprises:
setting the read voltage to a start voltage at which each memory cell is detected as having the same start state;
repeatedly incrementing/decrementing the read voltage by a step voltage and applying the read voltage to the memory cells until at least one memory cell is detected as having another state than the start state; and
setting the distribution edge equal to the read voltage at which the at least one memory cell is detected as having another state than the start state.

13. The method of claim 12, wherein determining the distribution gradient of the threshold voltage distribution in a distribution section comprises:
repeatedly incrementing/decrementing the read voltage by a step voltage and applying the read voltage to the memory cells;
counting in each case the memory cells being detected as having another state than the start state.

14. The method of claim 13, wherein determining the distribution gradient is terminated, if the number of memory cells being detected as having another state than the start state exceeds the number of repair cells.

15. A method of testing a cell array, comprising:
a) determining an distribution edge of a threshold voltage distribution of the cell array;
b) setting a test voltage equal to the distribution edge;
c) reading out the memory cells by applying the test voltage to each memory cell
d) counting memory cells showing a predetermined state;
e) incrementing/decrementing the test voltage by a step voltage;
f) repeating c) to e), wherein
a distribution gradient of the threshold voltage distribution in a distribution section near the outer distribution edge is determined,
the respective distribution gradient is compared to a limit gradient, and, in case of the distribution gradient exceeding the limit gradient, an inner distribution edge is assigned to a test voltage at which the distribution gradient exceeds the limit gradient, and
memory cells that exhibit a threshold voltage in a range between the outer distribution edge and the inner distribution edge are classified as being defective.

16. The method of claim 15, wherein the cell array comprises a plurality of memory cells configured to showing at least two distinguishable states, wherein a current state of each memory cell is detectable by applying a read voltage to the memory cell, wherein by applying a read voltage below a threshold voltage a first state of the respective memory cell is detectable and wherein by applying a read voltage beyond the threshold voltage a second state of the respective memory cell is detectable.

17. The method of claim 15, wherein c) to e) are repeated until the number of memory cells showing the predetermined state exceeds a predetermined maximum count.

18. The method of claim 15, wherein the cell array is classified as being non-defective if the distribution gradient is strictly monotonic increasing in a distribution section adjacent to a lower edge of the threshold voltage distribution or if the distribution gradient is strictly monotonic decreasing in a distribution section adjacent to an upper edge of the threshold voltage distribution.

19. The method of claim 15, wherein determining a lower or an upper distribution edge comprises:
a) setting a test voltage to a start voltage, wherein the start voltage is selected such that each memory cell shows a state being distinguishable from the predetermined state;
b) decreasing/increasing the test voltage by a step voltage;
c) reading out the memory cells by applying the test voltage; and
d) repeating b) to c) until at least one of the memory cells shows the predetermined state, wherein the distribution edge is set equal to the respective test voltage at which the at least one of the memory cells shows the predetermined state.

20. The method of claim 15, wherein the method is performed by circuitry provided within the memory device.

21. A memory device comprising:
a cell array including a plurality of memory cells, each memory cell being capable of showing at least two distinguishable states;
a programmable read voltage source adapted to supply an alterable read voltage; and
a test control unit comprising:
a voltage control unit for controlling the read voltage source;
a counter unit for counting the memory cells exhibiting a predetermined state; and
an analysis unit for rating a currently determined number of memory cells exhibiting the predetermined state.

22. The memory device of claim 21, wherein a first state of the respective memory cell is detectable by applying a read voltage below a threshold voltage and wherein a second state of the respective memory cell is detectable by applying a read voltage beyond the threshold voltage and wherein the threshold voltage depends on the respective current data contents.

23. The memory device of claim 21, wherein the test control unit further includes a storage unit configured to temporarily storing a previously determined number of memory cells exhibiting the predetermined state, wherein the analysis unit is configured to rating the cell array by comparing the currently determined number with the previously determined number of memory cells exhibiting the predetermined state.

24. The memory device of claim 21, wherein the test control unit further includes a step counter unit configured to counting a step number of increments/decrements applied to the read voltage source, wherein the analysis unit is configured to rating the cell array by comparing the currently determined number with a predetermined value assigned to the respective step number.

25. The memory device of claim 21, wherein the test control unit is further configured to classifying memory cells assigned to the previously determined number of memory cells as being defective.

26. The memory device of claim 25, further comprising repair cells and a repair unit configured to replacing defective memory cells with repair cells.

27. The memory device of claim 26, wherein the test control unit is further configured to controlling the repair unit such that memory cells being classified as being defective by the test control unit are repairable.

28. The memory device of claim 27, wherein the analysis unit is further configured to terminating comparing the currently determined number of memory cells exhibiting the predetermined state with the previously determined number of memory cells exhibiting the predetermined state when the currently determined number of memory cells exhibiting the predetermined state exceeds the number of available repair cells.

29. A memory device comprising:
a cell array including a plurality of memory cells, each memory cell being configured to showing at least two distinguishable states;
means for supplying a programmable read voltage, wherein the read voltage is alterable in steps defined by a step voltage;
means for controlling the read voltage source;
means for reading out the states of the memory cells;
means for determining a number of memory cells having a predetermined state;
means for storing the number of memory cells having the predetermined state;
means for comparing a currently determined number of memory cells having the predetermined state with a previously determined number of memory cells having the predetermined state; and
means for classifying memory cells as being defective on the basis of a comparison between the currently determined number of memory cells having the predetermined state with the previously determined number of memory cells having the predetermined state.
